(19) United States
(12) Patent Application Publication
(10) Pub. No.: US 2026/0361272 A1
(43) Pub. Date: Nov. 12, 2026

(54) AC Coupling Circuit and Transimpedance Amplifier

(71) Applicant: NTT, Inc., Chiyoda-ku, Tokyo (JP)

(72) Inventors: Atsushi Kanda, Musashino-shi, Tokyo (JP); Hirotaka Nakamura, Musashino-shi, Tokyo (JP); Yasuhiko Nakanishi, Musashino-shi, Tokyo (JP); Tadashi Minotani, Musashino-shi, Tokyo (JP); Masatoshi Tobayashi, Yokohama-shi, Kanagawa (JP); Nobuhiro Toyoda, Yokohama-shi, Kanagawa (JP); Masafumi Nogawa, Yokohama-shi, Kanagawa (JP); Yoshikazu Urabe, Kawasaki-shi, Kanagawa (JP)

(73) Assignee: NTT Innovative Devices Corporation, Chiyoda-ku, Tokyo (JP)

(21) Appl. No.: 19/129,773

(22) PCT Filed: Nov. 17, 2023
(86) PCT No.: PCT/JP2023/041443

§ 371 Date: May 14, 2025

(30) Foreign Application Priority Data
Nov. 18, 2022 (JP) 2022-184841

(51) Int. Cl. H03F 1/02; H03F 3/08; H03H 11/26

(52) U.S. Cl. CPC H03F 1/0233; H03F 3/082; H03H 11/26; H03F 2200/168

(57) ABSTRACT

A transimpedance amplifier which obtains a stable output voltage in a short time regardless of the timing of a control signal is provided. The transimpedance amplifier includes a transimpedance amplifier core circuit for amplifying a current input to an input terminal with a desired gain and outputting the current as a voltage signal; one or more buffer circuits for amplifying differentially the voltage signal and outputting an output signal; and an AC-coupling circuit disposed between the transimpedance amplifier core circuit and the buffer circuit or between the buffer circuits, the AC-coupling circuit switching between two different time constants in accordance with an amplitude of the output signal, and in the AC-coupling circuit, switching time required from a small time constant to a large time constant is longer than switching time required from the large time constant to the small time constant.

### TECHNICAL FIELD

The present invention relates to an AC-coupling circuit that inputs and outputs signals with different amplitudes and to a transimpedance amplifier to which the AC-coupling circuit is applied.

### BACKGROUND ART

In optical transmission devices such as optical transmission systems and passive optical network (PON) systems that enable high-speed data transmission, a transimpedance amplifier (TIA) is used in an optical receiving circuit that converts an optical signal into an electrical signal. A photocurrent obtained by optical/electrical conversion of a received optical signal using a light receiving element such as a photodiode (PD) is input to the TIA. The input current is current-voltage-converted by an impedance conversion gain proportional to the value of feedback resistance, and a converted voltage is output.

In a PON system, upstream packet data from each of a plurality of subscriber-side devices (Optical Network Units: ONUs) to a station-side device (Optical Line Terminal: OLT) is sent in bursts by time-division multiplexing. Since paths and distances between each ONU and the OLT are different, optical signals that reach the OLT have different optical powers for each packet. Thus, in the light receiving element in the optical receiving circuit of the OLT, the electrical signal of the photocurrent obtained by optical/electrical conversion has a different signal amplitude for each packet.

Generally, upstream packet data includes a specific pattern portion (preamble pattern) for signal reproduction located at the beginning of a packet, and a subsequent data portion (payload). An alternating (repeated) signal of 1/0 (Hi/Lo) is often used as a preamble pattern.

FIG. 1 is a diagram showing a configuration of a conventional TIA. A TIA 10 connected to a PD includes a TIA core circuit 11 that amplifies a photocurrent input to an input terminal with a desired gain and outputs the photocurrent as a voltage signal, and a buffer (amplifier) circuit 12 that amplifies differentially and outputs an output signal from the core circuit. Further, the core circuit 11 and the buffer circuit 12 are connected using an AC-coupling circuit (i.e., a high-pass filter: HPF) including capacitor C, a resistor R1, and a resistor R2. An output of the AC-coupling circuit is connected to one input of the buffer circuit 12, and a reference voltage VREF is input to the other input.

The core circuit 11 converts the photocurrent of the PD and outputs a voltage in a single-ended format. The buffer circuit 12 outputs an electrical signal corresponding to an optical signal received in a differential format centered on the VREF to a stage subsequent to the TIA.

FIG. 2 is a diagram showing the time constant dependence of an output voltage in a conventional TIA. Each diagram in FIG. 2 is a schematic drawing of the vicinity of a boundary between packets from different ONUs, and there is a guard time where no data exists between two packets. As a core circuit 11 output voltage shows in the upper diagram in FIG. 2, packets 1 and 2 from ONUs at different distances have different amplitudes. Since the output voltage of the TIA core circuit 11 is a single-ended output, the packets 1 and 2 also have different DC components. Ideally, the AC-coupling circuit in the TIA 10 should have the property of removing only the DC component of an input signal to provide only the AC component of a data signal to the buffer circuit 12. However, in the TIA using the AC-coupling circuit, in a case where packets with different signal amplitudes are input, time until a normal packet signal is output is affected by the time constant of the AC-coupling circuit.

As described above, in a case where an optical signal is received from an ONU near the OLT, the signal amplitude of the output voltage of the TIA core circuit 11 is large (packet 1), and in a case where an optical signal is received from an ONU far from the OLT, the signal amplitude of the output voltage of the TIA core circuit 11 is small (packet 2). The DC component of the output voltage of the TIA core circuit 11 also changes for each packet and changes in a step-like manner near a boundary between packets. In a case where the time constant of the HPF is relatively large and a cutoff frequency is low, a slow step-like change due to a transmitted low-frequency component appears in an output from the buffer circuit 12 as shown in FIG. 2. Conversely, in a case where the time constant of the HPF is relatively small and a cutoff frequency is too high, as shown in FIG. 2, a sag occurs in the pulse waveform of the output from the buffer circuit 12, and the data waveform itself is distorted. There is a trade-off relationship between blocking the DC component of a packet and maintaining a pulse waveform.

In a case where the time constant of the AC-coupling circuit is small, time until a normal packet signal is output from the buffer circuit 12 is short in quick response to a DC component variation near the packet boundary. However, in a case where a long sequence of identical codes is included in a payload in a packet, the VREF of the output voltage of the buffer circuit 12 cannot be held for time required to distinguish the codes, which results in misidentification. Conversely, in a case where the time constant is made large so that the VREF can be held for a sequence of identical codes included in the payload, the time until a normal packet signal is output becomes long. There is also a trade-off relationship between accurate data identification for the sequence of identical codes and quick adaptation to the DC component variation near the packet boundary. Thus, there is known a configuration of switching between time constants by changing the capacitance value and resistance value of the AC-coupling circuit using an external control signal.

FIG. 24 is a diagram showing a configuration of a conventional TIA that changes a time constant (Patent Literature 1). A TIA 11-1 has an automatic gain control (AGC) circuit 13 of the TIA core circuit 11 and an automatic offset control (AOC) circuit 14 for the DC offset of a differential output from the buffer circuit 12. The TIA 11-1 has a configuration of switching between a state where the time constant is small and a state where the time constant is large in the AGC circuit 13 and the AOC circuit 14. The state where the time constant is small is a state where the time until a normal packet signal is output is short, and the state where the time constant is large corresponds to a state where holding power for a sequence of identical codes included in a packet signal is high. A switch between the time constants of the AC-coupling circuit 15 is made using a reset control signal (RESET).

### CITATION LIST

### Patent Literature

PTL 1: Japanese Patent No. 5731615

### SUMMARY OF INVENTION

### Technical Problem

In order to obtain a packet signal output in a short time and also to hold a necessary sequence of identical codes, a configuration in which the time constant is reduced in a preamble portion at the beginning of a packet to obtain a normal signal output, and then the time constant is increased is conceivable. However, in the circuit disclosed in Patent Literature 1, in the case of using a configuration in which the time constant is reduced in the preamble portion at the beginning of the packet to obtain a normal signal output, and then the time constant is increased, there arises such a problem that the time until a normal output voltage is obtained depends greatly on the timing of a control signal.

FIG. 3 is a diagram showing the output voltage of the AC-coupling circuit in a case where the time constant in a conventional TIA is changed from small to large in a short time. FIG. 3 shows the output voltage of the AC-coupling circuit in a case where in the TIA 11-1 shown in FIG. 24, a reset control signal (RESET) given from the outside to reset the AOC circuit 14 is applied with a shifted timing to an input voltage to the AC-coupling circuit 15. A reset period is a period that includes a guard time during which packets from different ONUs are switched.

FIG. 4 is an enlarged view of the reset period in FIG. 3. Specifically, (A) in FIG. 4 shows reset control signals (Hi-Lo-Hi) 1-0 to 1-9 shifted at intervals of 1/10 of one period of an AC-coupling input voltage. For example, between the reset control signal 1-0 that becomes Lo at the timing of a point a (110 ns) and the next reset control signal 1-1, there is a 1/10 period of the AC-coupling input voltage, that is, a phase is shifted by 36°. Between the reset control signal 1-0 and the reset control signal 1-5, there is a 5/10 period of the AC-coupling input voltage, that is, a phase is shifted by 180°. (B) in FIG. 4 shows a change in the time constant T of an AC-coupling circuit indirectly obtained by monitoring the potential difference between certain nodes in the TIA 11-1. A period during which the reset control signal is Hi roughly matches a state where the time constant is large, and a period during which the reset control signal is Lo roughly matches a state where the time constant is small. (C) and (D) in FIG. 4 respectively show the waveforms of the input voltage and the output voltage of the AC-coupling circuit 15. In order to intelligibly explain the timing of the reset control signal, a sine wave is used as an input signal.

Here, there will be considered the case of the reset control signal 1-0 that becomes Lo at the point a (110 ns) where the amplitude value of the input voltage is 0 and the phase is 0° and becomes Hi at a point b (140 ns) where the phase is 0°. In a case where the reset control signal is in a Lo state, the time constant is very small, so that the cutoff frequency of the HPF is higher than a sine wave frequency. For this reason, the output voltage of the AC-coupling circuit in (D) disappears at the point a, and an output voltage waveform 2-0 immediately appears at the point b, which is an edge where the time constant switches to Hi. At the point b, an output is produced from an initial state where the instantaneous amplitude of the sine wave is 0 and the phase is 0°, so that the output voltage waveform 2-0 does not have a DC component, and a sine wave of a normal AC-coupling output is immediately obtained.

Next, there will be considered the case of the reset control signal 1-1 with a phase shifted by 36°. As the output voltage of the AC-coupling circuit in (D), an output voltage waveform 2-1 appears at a timing with a 36° phase delay from the point b. At this time, the output voltage waveform 2-1 starts from the initial state of an amplitude value on the positive side, reaches a positive peak, and then decreases to the negative side. As a result, the AC-coupling output forms the output waveform 2-1, with the DC component shifted to the negative side.

There will be considered the case of the reset control signal 1-2 with a phase further shifted from the reset control signal 1-1 by 36°. As the output voltage of the AC-coupling circuit in (D), an output voltage waveform 2-2 appears at a timing with a 72° phase delay from the point b. The AC-coupling output forms the output voltage waveform 2-2 with a DC component further increased on the negative side as compared to the output waveform 2-1. In the output waveforms 2-1 and 2-2 with the DC component shifted, the DC component gradually converges to 0 over time as shown in FIG. 3, and a normal AC-coupling output is obtained.

There will be considered the case of the reset control signal 1-5 with a phase shifted from the reset control signal 1-0 by 180°. As the output voltage of the AC-coupling circuit in (D), an output voltage waveform 2-5 appears at a timing with a 1800 phase delay from the point b. Since an output is produced from an initial state where the instantaneous amplitude of the sine wave is 0, the DC component of the output voltage waveform 2-5 is 0 V as a result, and in a state where the reset control signal is Hi where the time constant is large, a sine wave of a normal AC-coupling output is immediately obtained.

As described above, in a case where the reset control signal changes from Lo to Hi and the time constant changes from a small time constant to a large time constant, the initial value of an output voltage appearing from an AC-coupling circuit at the edge of a reset control signal changes depending on the timing of the reset control signal. Depending on the initial value, a DC component included in the output signal of the AC-coupling circuit also varies depending on the timing of the reset control signal. As a result, the time until the DC component converges to 0 (VREF) and a normal AC-coupling output voltage is obtained changes depending on the timing of application of the reset control signal.

Since distances from each ONU to the OLT are different, the OLT controls a packet transmission timing from each ONU based on round-trip time between the OLT and the ONU. However, since the round-trip time varies, the timing of a packet arriving at the TIA circuit of the OLT also varies. This means that it is impossible to match the timings of reset control signals with respect to the sine wave in FIGS. 3 and 4.

### Solution to Problem

An object of the present invention is to provide an AC-coupling circuit and a transimpedance amplifier for obtaining a stable output voltage in a short time regardless of the timing of a control signal.

In order to achieve such an object, one embodiment of an AC-coupling circuit according to the present invention is characterized in that the AC-coupling circuit includes a switching means for switching between two different time constants in accordance with an input signal amplitude and that switching time required for a switch from a small time constant to a large time constant is longer than switching time required for a switch from the large time constant to the small time constant.

Further, one embodiment of a transimpedance amplifier includes a transimpedance amplifier core circuit for amplifying a current input to an input terminal with a desired gain and outputting the current as a voltage signal, one or more buffer circuits for amplifying differentially the voltage signal from the transimpedance amplifier core circuit and outputting an output signal, and an AC-coupling circuit disposed between the transimpedance amplifier core circuit and the buffer circuit or between the buffer circuits, the AC-coupling circuit switching between two different time constants in accordance with an amplitude of the output signal, wherein switching time required for a switch from a small time constant to a large time constant is longer than switching time required for a switch from the large time constant to the small time constant.

### Advantageous Effects of Invention

According to the present invention, it is possible to provide an AC-coupling circuit and a transimpedance amplifier capable of obtaining a stable output voltage in a short time regardless of the timing of a control signal.

### BRIEF DESCRIPTION OF DRAWINGS

FIG. 1 is a diagram showing a configuration of a conventional TIA.

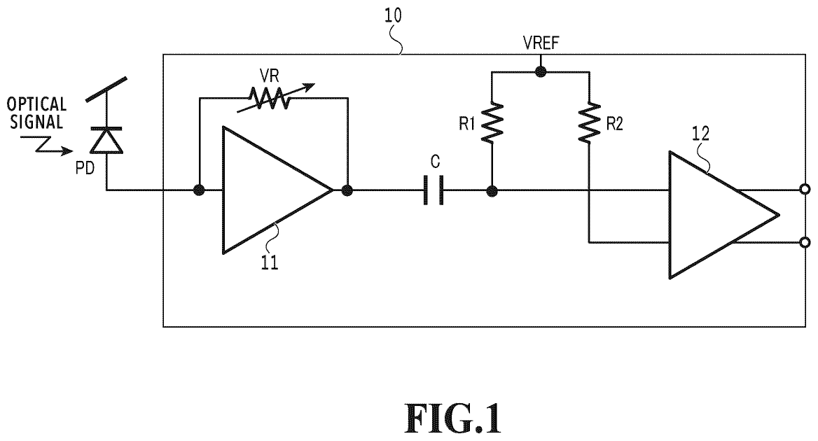

FIG. 2 is a diagram showing the time constant dependency of an output voltage in the conventional TIA.

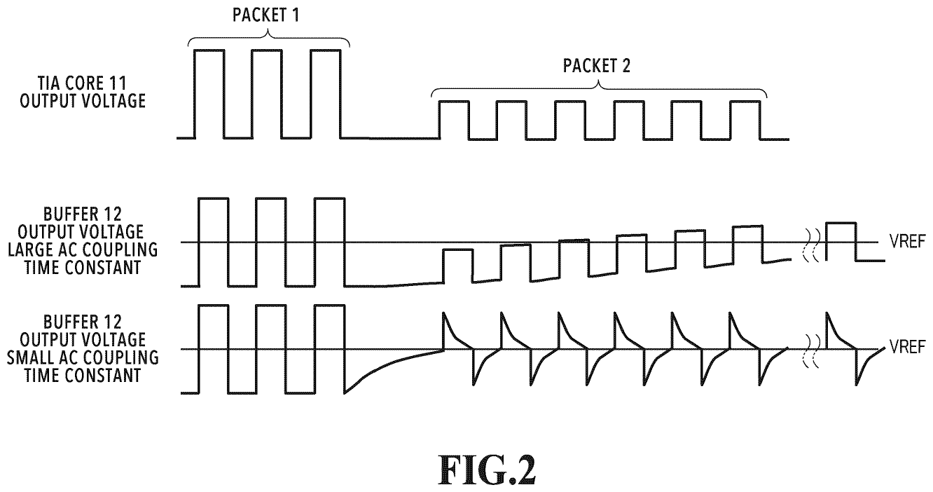

FIG. 3 is a diagram showing the output voltage of an AC-coupling circuit in a case where a time constant in the conventional TIA is changed from small to large in a short time.

FIG. 4 is an enlarged view of a reset period in FIG. 3.

FIG. 5 is a diagram showing the operational concept of a TIA according to a first embodiment of the present invention.

FIG. 6 is a diagram showing a configuration of the TIA according to the first embodiment.

FIG. 7 is a diagram showing time constant control of an AC-coupling circuit of the TIA according to the first embodiment.

FIG. 8 is a diagram showing the output voltage of the AC-coupling circuit in a case where the time constant of the TIA according to the first embodiment is gradually changed from small to large.

FIG. 9 is an enlarged view of a reset period in FIG. 8.

FIG. 10 is a diagram showing time constant control of an AC-coupling circuit of a TIA according to a second embodiment.

FIG. 11 is a diagram showing a variation in an electric charge stored in the capacitor of the AC-coupling circuit.

FIG. 12 is a diagram showing a relationship between a difference of a VREF from a sine wave amplitude center value and an output waveform duty ratio.

FIG. 13 is a diagram showing a relationship between the average voltage of an AC-coupling output voltage and an allowable VREF range.

FIG. 14 is a diagram showing a low-pass filter in which the amplitude of an output signal is 1/10 of the amplitude of an input signal.

FIG. 15 is a diagram showing a variation in the average voltage of the output signal of a primary low-pass filter.

FIG. 16 is a diagram showing a time constant control signal generation circuit of a TIA according to a third embodiment.

FIG. 17 is a diagram showing a configuration of the TIA according to the third embodiment.

FIG. 18 is a diagram showing a circuit configuration of an AC-coupling circuit and a time constant control signal generation circuit.

FIG. 19 is a diagram showing time constant control by the time constant control signal generation circuit.

FIG. 20 is a diagram showing the output voltage of the AC-coupling circuit in a case where the time constant of the TIA according to the third embodiment is gradually changed from small to large.

FIG. 21 is an enlarged view of a reset period in FIG. 20.

FIG. 22 is a diagram showing the output voltage of the AC-coupling circuit in a case where the time constant of the TIA according to the third embodiment is gradually changed from small to large.

FIG. 23 is a diagram showing the output voltage of the AC-coupling circuit in a case where the time constant of the TIA according to the third embodiment is gradually changed from small to large.

FIG. 24 is a diagram showing a configuration of a conventional TIA that switches between time constants.

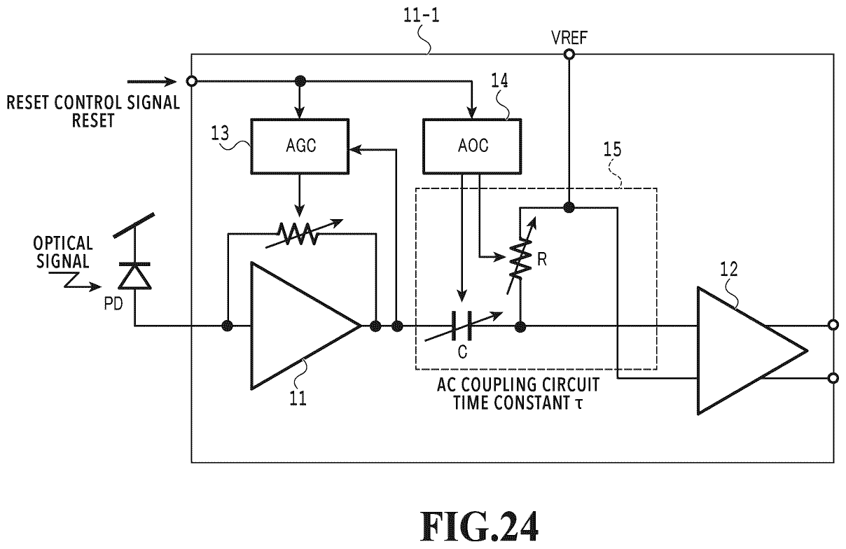

### DESCRIPTION OF EMBODIMENTS

Hereinafter, embodiments of the present invention will be described in detail with reference to the drawings.

### First Embodiment

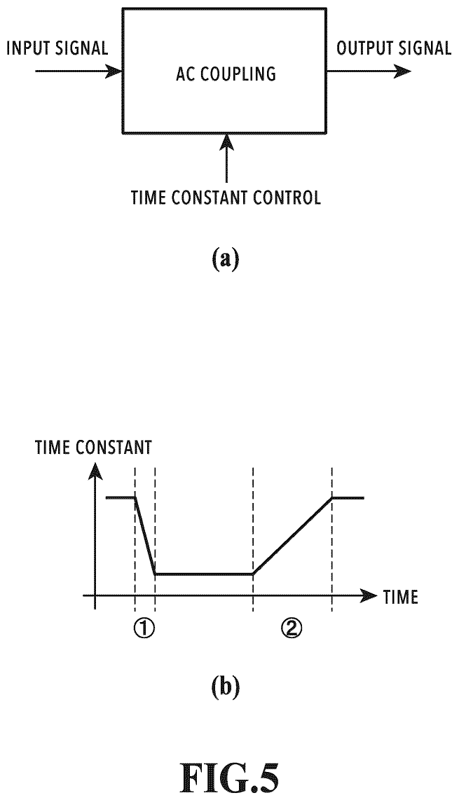

FIG. 5 is a diagram showing the operation concept of a TIA according to a first embodiment of the present invention. As shown in FIG. 5(a), an AC-coupling circuit according to the first embodiment has a switching means for switching between two different time constants in accordance with an input signal amplitude. Here, “switching between two different” means that there are two aspects of switching between different time constants. Specifically, as shown in FIG. 5(b), two different time constants are set, and a switch from a large time constant to a small time constant or a switch from the small time constant to the large time constant is made. At this time, switching time (2) required for a switch from the small time constant to the large time constant is longer than switching time (1) required for a switch from the large time constant to the small time constant.

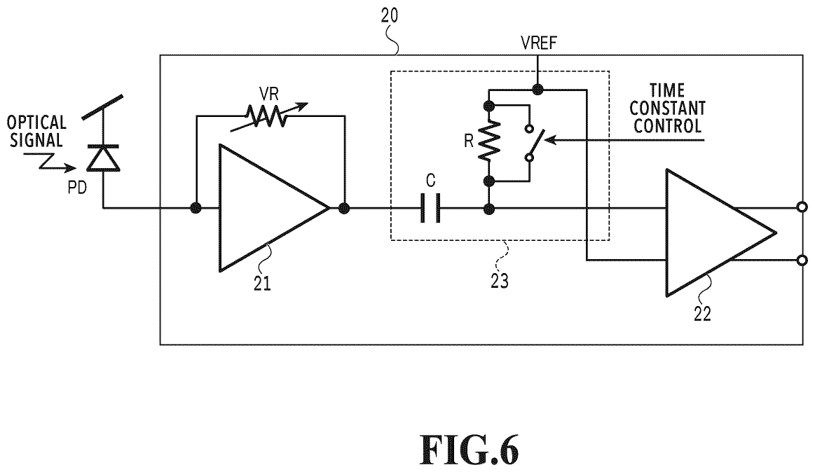

FIG. 6 is a diagram showing the configuration of the TIA according to the first embodiment. A TIA 20 connected to a PD includes a TIA core circuit 21 that amplifies a photocurrent input to an input terminal with a desired gain and outputs the photocurrent as a voltage signal, a buffer circuit 22 that amplifies differentially and outputs an output signal from the core circuit, and an AC-coupling circuit 23 that connects the TIA core circuit 21 and the buffer circuit 22. The AC-coupling circuit 23 includes capacitor C that connects the two in series and a resistor R that is connected in parallel and forms a so-called high-pass filter.

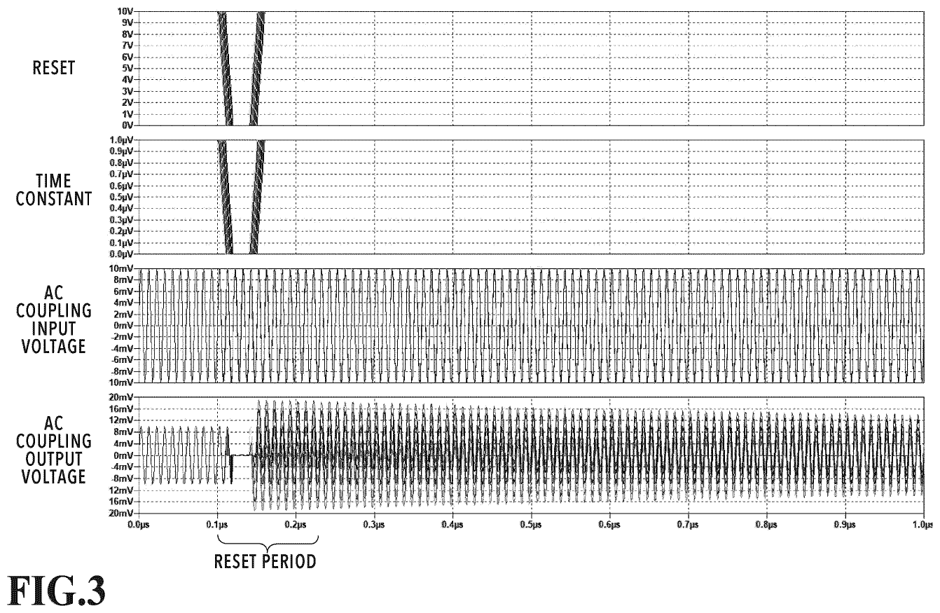

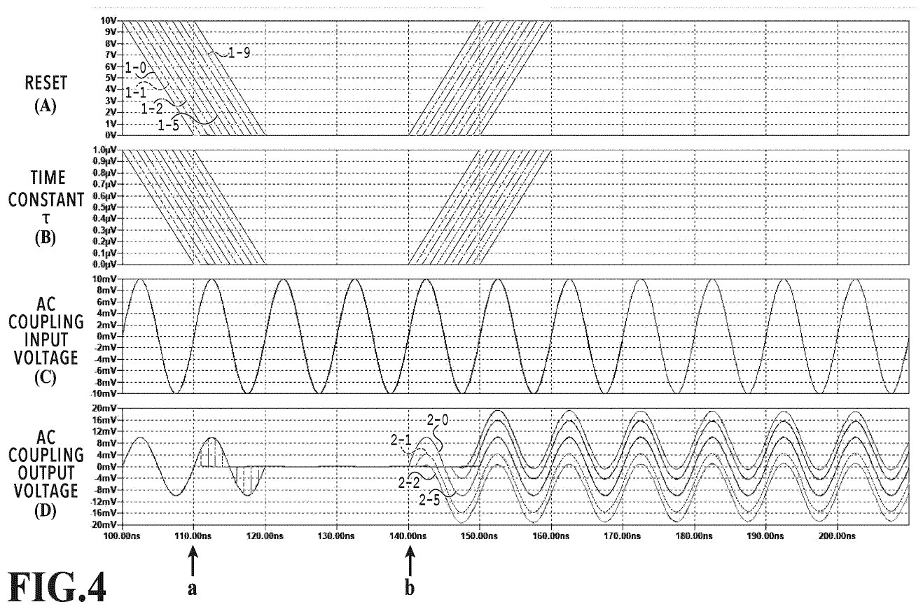

Further, a switch SW which is connected in parallel with the resistor R and shorts out the resistor R is provided. The switch SW is controlled to be on/off with a time constant control signal (RESET) given from the outside, thereby changing the resistance value of the resistor forming the high-pass filter and switching between two different CR time constants of the AC-coupling circuit 23. Incidentally, in the following description, the time constant control signal (RESET) corresponds to the reset control signal described in FIGS. 3 and 4. The time constant control signal (RESET) from Hi to Lo to Hi is used to switch between the two different time constants shown in FIG. 5(b).

Incidentally, in the configuration shown in FIG. 6, although the switch SW connected in parallel to the resistor R is controlled to be on/off, for example, a plurality of resistors and switches may be used to switch between two resistance values and change the time constant.

Additionally, in the configuration shown in FIG. 6, although the AC-coupling circuit is disposed between the TIA core circuit and the buffer circuit, in a case where the buffer circuit is configured in a multiple-stage manner, the function and effect of the present invention can be obtained even in the case of being disposed between the buffer circuits.

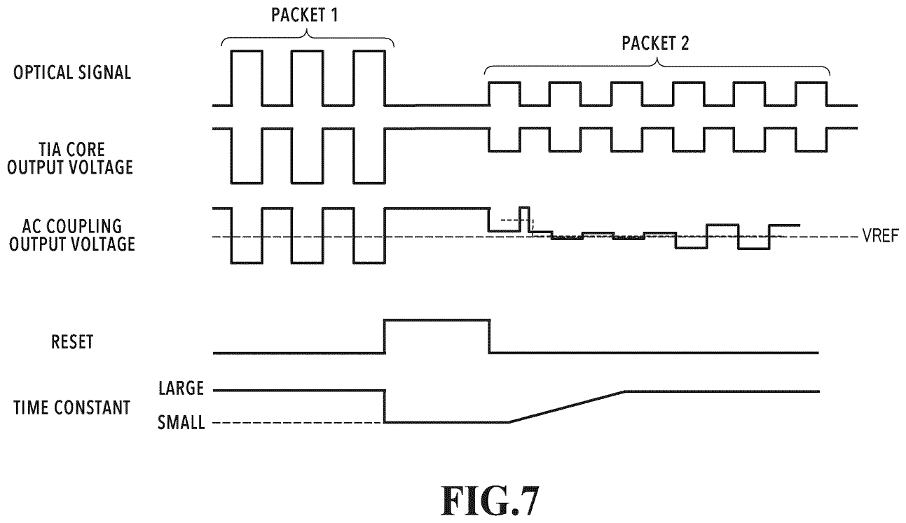

FIG. 7 is a diagram showing the time constant control of the AC-coupling circuit of the TIA according to the first embodiment. In the above-mentioned PON system, the OLT receives an optical signal from a plurality of ONUs by time sharing. The output voltage of the TIA core circuit 21 varies depending on the intensity of the received optical signal, and the output voltage of the AC-coupling circuit 23 is significantly affected by a change in the time constant in a case where a packet 2 with a small signal amplitude is input. Thus, in the TIA 20, in a case where the packet 2 is input, time constants are switched as shown in FIG. 5(b) using the time constant control signal (RESET) given from the outside.

Specifically, the OLT is provided with a guard time between periods of reception from each ONU. During this guard time, the time constant control signal (RESET) is output, and time constant control is performed so that switching time required for a switch from a small time constant to a large time constant is longer than switching time required for a switch from the large time constant to the small time constant. The period between the packet 1 and the packet 2 where there is no optical signal is the guard time and has a length of about several pulses, but FIG. 7 is a schematic diagram, and the time relationship is not limited to the example in FIG. 7.

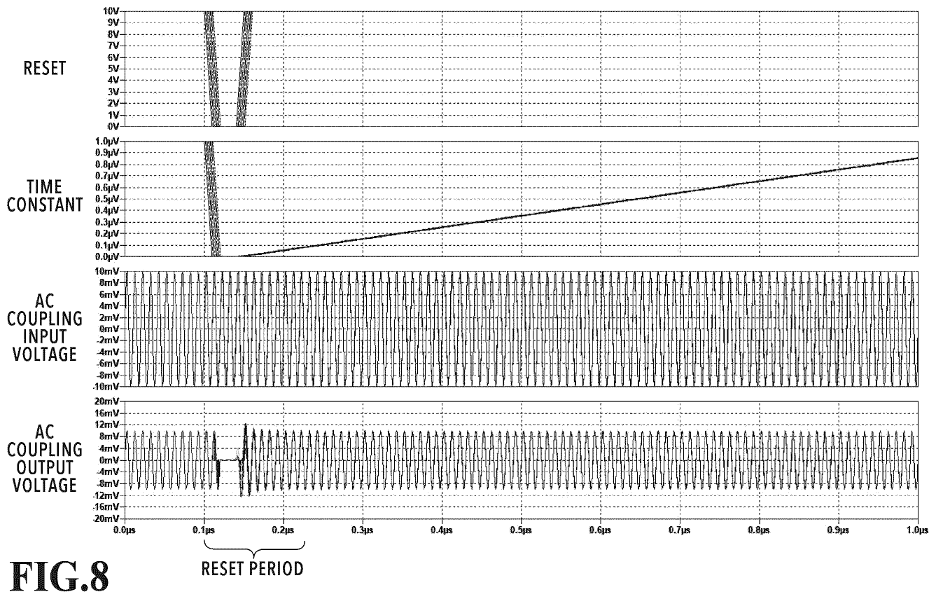

FIG. 8 is a diagram showing the output voltage of the AC-coupling circuit in a case where the time constant of the TIA according to the first embodiment is gradually changed from small to large. FIG. 8 corresponds to respective waveforms in FIG. 3 in the description of the conventional art. Comparison between the waveform of the time constant in FIG. 3 and the waveform of the time constant in FIG. 8 shows that the period during which the time constant switches from small to large is several tens of times longer and that the time constant changes slowly from small to large. Further, the output voltage of the AC-coupling circuit has almost no variation in the DC component, and a normal AC-coupling output is obtained immediately in about two periods of a sine wave.

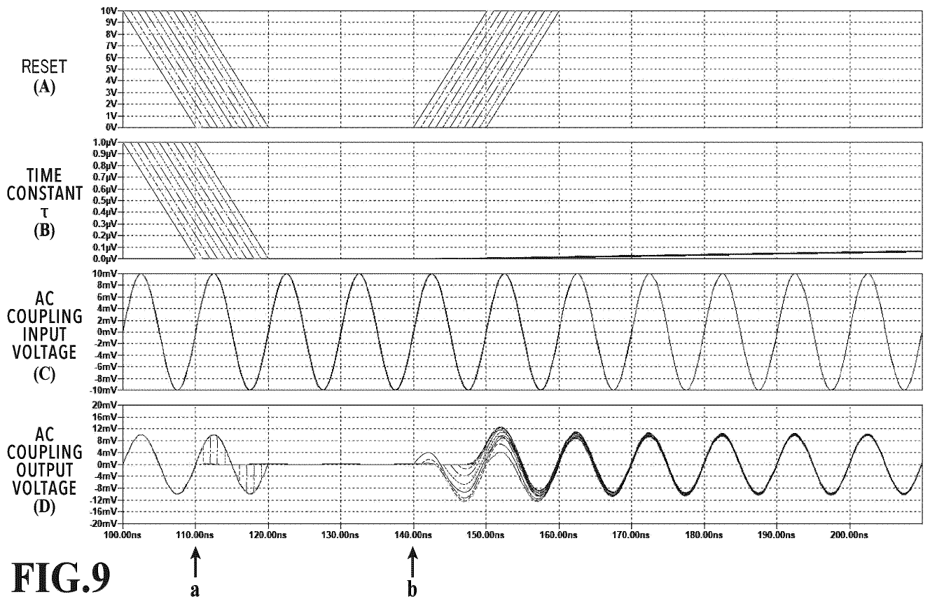

FIG. 9 is an enlarged view of a reset period in FIG. 8. Comparison between (B) in FIG. 4 and (B) in FIG. 9 shows that the switching time required for a switch from a small time constant to a large time constant is very long. In the TIA according to the first embodiment, regardless of the timing of the reset control signal, the DC component converges to 0 for 10 to 20 ns from the rising edge of the reset control signal from Lo to Hi.

In the output voltage waveform shown in FIG. 4, the Lo state of the reset control signal roughly coincides with the state of the small time constant, and the Hi state roughly coincides with the state of the small time constant. From the moment of the rising edge from Lo to Hi, the HPF enters a state with no attenuation for the sine wave frequency, and an input voltage immediately appears as it is. Thus, the instantaneous initial value of the output voltage of the AC-coupling circuit varies depending on the phase of an output sine wave at the timing of the rising edge. The DC component also varies depending on the timing of the reset control signal, and time required to reach a normal AC-coupling output varies.

In contrast, in the output voltage waveform shown in (D) in FIG. 9, the input voltage does not appear immediately without attenuation from the rising edge of the time constant control signal (reset control signal) from Lo to Hi, but gradually appears (ramps up). This is because since the time constant changes very slowly from small to large as shown in (B) in FIG. 9, the cutoff frequency of the HPF of the AC-coupling circuit also changes slowly as compared to the conventional configuration. Since the amount of attenuation of the HPF of the AC-coupling circuit for the sine wave frequency gradually decreases from a maximum attenuation state, the output voltage gradually appears from the time of the rising edge. At the rising edge from Lo to Hi in the time constant control signal, since the HPF is still in a large attenuation state, the initial value of the output voltage of the AC-coupling circuit is in the region of 0. Regardless of the timing of the rising edge, the initial value of the output voltage is about 0 and the DC component is also about 0, so that a normal AC-coupling output is immediately obtained in about two periods of a sine wave.

As described above, since the switching time required for a switch from a small time constant to a large time constant is sufficiently large as compared to a change in the phase of an AC-coupling input voltage, a normal output voltage is obtained regardless of the timing of the time constant control signal (RESET). As can be seen by comparing the AC-coupling output voltage in FIG. 4 with the AC-coupling output voltage in FIG. 9, in the TIA 20, a normal output voltage can be obtained in a short time of about 20 ns from the rising of the time constant control signal (RESET).

### Second Embodiment

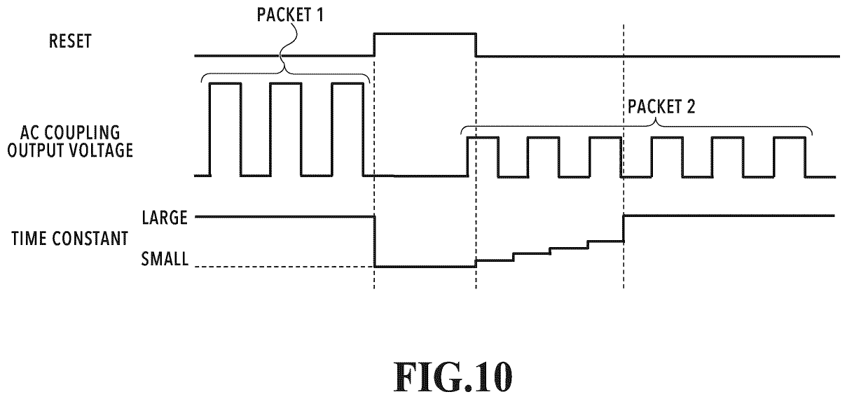

FIG. 10 is a diagram showing the time constant control of the AC-coupling circuit of a TIA according to a second embodiment of the present invention. Although the switching time required for a switch from a small time constant to a large time constant is also longer than the switching time required for a switch from the large time constant to the small time constant in the TIA according to the second embodiment, there is a difference from the first embodiment in that the time constant is changed discretely from the small time constant to the large time constant through a plurality of steps. For example, in the configuration shown in FIG. 6, in order to change the time constant, a plurality of resistors may be prepared as the resistor R of the AC-coupling circuit 23 and switching may be performed using a switch to discretely change the time constant from the small time constant to the large time constant.

Here, in a case where the time constant is changed from the small time constant to the large time constant, a lower limit and an upper limit for the time constant will be quantitatively considered using a concrete example.

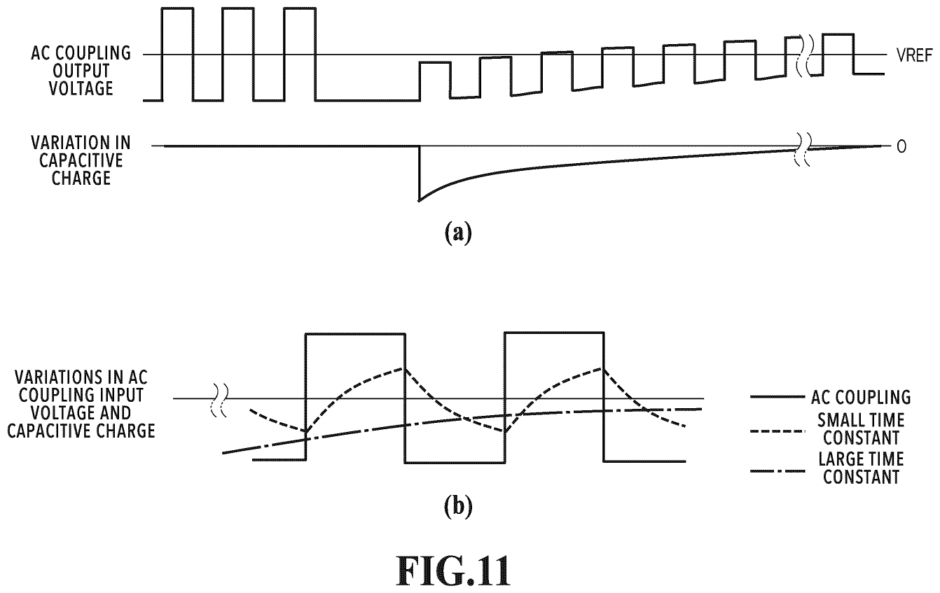

FIG. 11 is a diagram showing a variation in an electric charge stored in the capacitor of the AC-coupling circuit. FIG. 11(a) shows the relationship between the AC-coupling output voltage and the variation in the electric charge stored in the capacitor of the AC-coupling circuit. A potential difference V between the input and output of the AC-coupling circuit is determined based on the electric charge amount Q of the capacitor C, and is expressed by the following expression:

Q=CV Expression (1)

In a steady state, the electric charge stored in the capacitor is constant. After that, in a case where the packet 2 with a small signal amplitude is input, charging and discharging of an electric charge occur. Response time at this time is time taken for the amount of charge and discharge to become constant and for the electric charge to become constant. The operation until the electric charge becomes constant due to the charging and discharging is determined depending on the time constant of the AC-coupling circuit, and the result of the charging and discharging of the electric charge affects the AC-coupling output voltage.

FIG. 11(b) shows a relationship between the amounts of variation in the electric charge with respect to two types of time constants, a small time constant and a large time constant. In order to keep the time until a normal output voltage is obtained within a predetermined time, regardless of the AC-coupling input voltage and the timing of changing the time constant from the small time constant to the large time constant, it is only required that the amount of variation in the electric charge be within a certain range. In order to keep the amount of variation in the electric charge within a certain range, it is only required that the average voltage of the AC-coupling output voltage be within a certain range around the center voltage for an amplitude. In amplifying the output of the AC-coupling circuit using a buffer circuit, a reference voltage VREF is set as shown in FIG. 6 as the reference voltage of the amplifier.

However, in a case where a difference occurs in the average voltage of the AC-coupling output voltage with respect to the reference voltage, the duty ratio of the output waveform of the AC-coupling output voltage varies. Thus, as the definition of the amount of variation in the electric charge of the capacitor, that is, the range of the average voltage, the allowable value of the duty ratio in the output waveform is used. For the sake of generalization, an input waveform is herein assumed to be a sine wave.

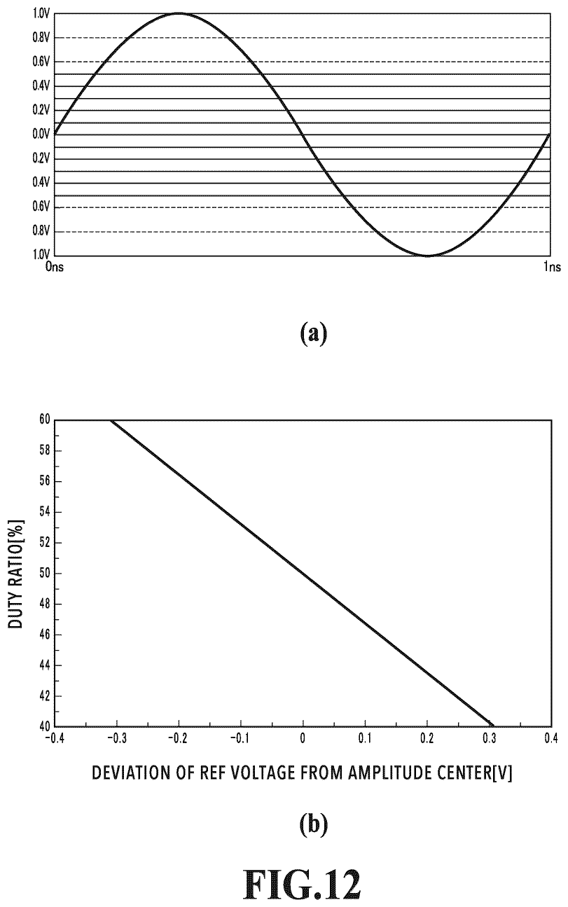

FIG. 12 is a diagram showing a relationship between a difference of the VREF from a sine wave amplitude center value and the output waveform duty ratio. For simplicity's sake, in FIG. 12(a), a duty ratio in a case where the sine wave amplitude is ±1 V, the frequency is 1 GHz, and the VREF is varied by ±0.5 V in 0.1 V steps is obtained. FIG. 12(b) shows a relationship between the duty ratio and the value of a deviation of the VREF from the sine wave amplitude center value. From this relationship, it can be seen that in a case where a certain allowable duty ratio is determined, an allowable VREF range for the certain allowable duty ratio is given by the following expression:

VREF variation range[V]=allowable duty ratio[%]/33 Expression(2)

For example, in a case where a variation in the allowable duty ratio is ±3.3% or less, the VREF variation range is about ±0.1 V or less.

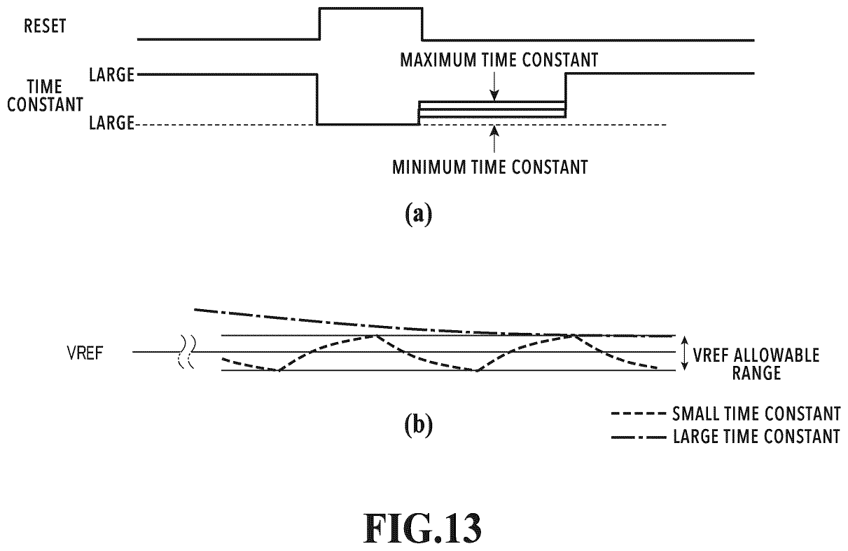

FIG. 13 is a diagram showing a relationship between the average voltage of the AC-coupling output voltage and the allowable VREF range. For the allowable VREF variation range obtained above, the maximum value and minimum value of a response time constant are obtained under the condition that a change in time of the response time constant is constant. Specifically, as shown in FIG. 13(a), in a case where the time constant is changed stepwise from a small time constant to a large time constant, the maximum value and minimum value of the time constant in the case of being changed through only one step on the way are obtained. As shown in FIG. 13(b), in a case where the time constant is small, it is only required that the average voltage of the AC-coupling output voltage be within the VREF allowable range. That is, the allowable value of the duty ratio in the output waveform of the AC-coupling output voltage is satisfied, and the amount of variation in the electric charge is within a predetermined range in the capacitance of the AC-coupling circuit. On the other hand, in a case where the time constant is large, it is only required that the average voltage of the AC-coupling output voltage be within the VREF allowable range within desired response time.

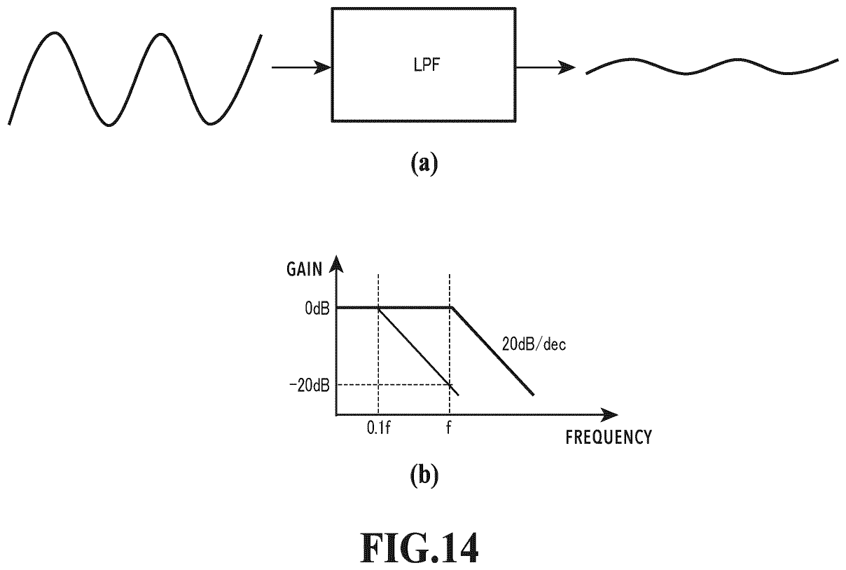

There will be considered a case where the VREF variation range is about ±0.1 V or less, that is, the case of 1/10 of the sine wave amplitude of an input waveform, in a case where a variation in the allowable duty ratio is ±3.3%. At this time, for a lower limit for the time constant, since it is only required that the average voltage of the AC-coupling output voltage be within the VREF allowable range, it is only required that the average voltage of the input waveform be ±10% or less of the amplitude. Thus, as shown in FIG. 14(a), a primary low-pass filter including the capacitor C and the resistor R is assumed as a circuit in which the amplitude of an output signal is 1/10 of an input signal. As shown in FIG. 14(b), it is only required that the CR time constant of the low-pass filter be set as shown in the following expression so that the cutoff frequency is 1/10 of the frequency of the input signal.

$$\begin{matrix}[ Mathematical Expression 1 ] & \\ C R > \frac{1}{2 π \times 0.1 f} & Expression 3\end{matrix}$$

Here, f is the frequency of the input signal. On the other hand, an upper limit for the time constant is the desired response time as mentioned above.

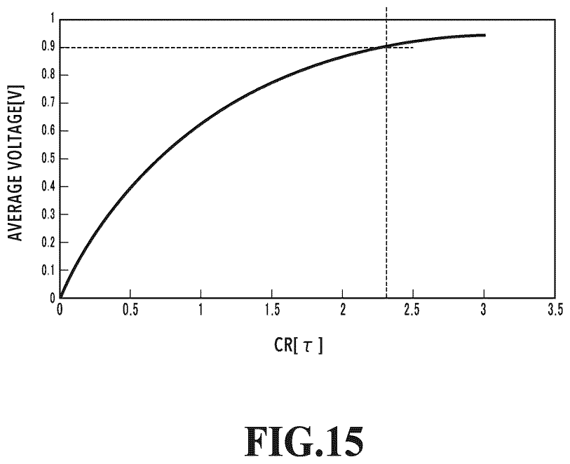

FIG. 15 is a diagram showing a variation in the average voltage of the output signal of the primary low-pass filter. In the case of the primary low-pass filter, the variation in the average voltage of the output signal is expressed by the following expression.

$$\begin{matrix}[ Mathematical Expression 2 ] & \\ v ( t ) = E ( 1 - {e}^{- \frac{1}{C R} t} ) & Expression 4\end{matrix}$$

In a case where a variation in the allowable duty ratio is ±3.3%, as shown in FIG. 15, the time (time constant) at which the average voltage is ±10% or less (0.9 or more) is 2.32 CR. That is, in a case where the desired response time is Tₛₑₜₜₗₑ, the following relationship is obtained.

$$\begin{matrix}[ Mathematical Expression 3 ] & \\ C R < \frac{{T}_{s e t t l e}}{2.32} & Expression 5\end{matrix}$$

Thus, in changing the time constant from a small time constant to a large time constant, the time constant has the following relationship with respect to the lower limit value and the upper limit value.

$$\begin{matrix}[ Mathematical Expression 4 ] & \\ \frac{1}{2 π \times 0.1 f} < C R < \frac{{T}_{s e t t l e}}{2.32} & Expression 6\end{matrix}$$

Alternatively, in a case where the waveform of the input signal is a sine wave, the following relationship holds.

$$\begin{matrix}[ Mathematical Expression 5 ] & \\ \frac{1}{2 π A f} < C R < \frac{{T}_{s e t t l e}}{- {log}_{e} A} A = \frac{allowable duty ratio [ \% ]}{33} & Expression 7\end{matrix}$$

### Third Embodiment

In the second embodiment, a lower limit and an upper limit for the time constant are obtained in a case where the time constant is changed stepwise from a small time constant to a large time constant. In a third embodiment, a method for continuously changing the time constant from a small time constant to a large time constant will be described.

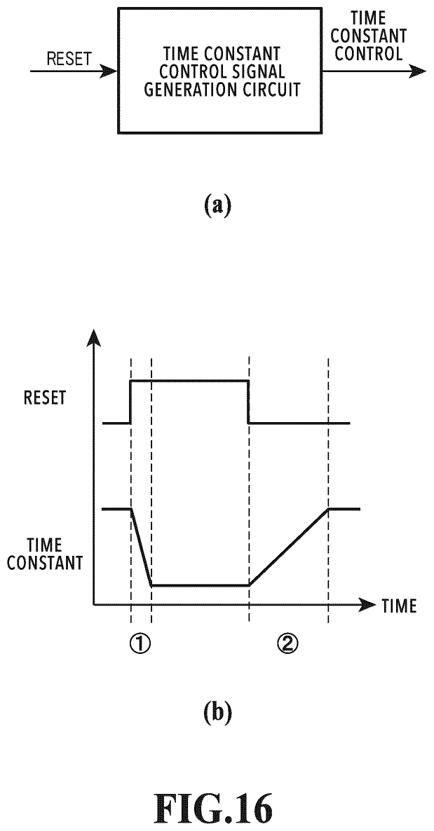

FIG. 16 is a diagram showing a time constant control signal generation circuit of a TIA according to the third embodiment of the present invention. As shown in FIG. 16(a), the time constant control signal generation circuit generates a time constant control signal from, for example, a pulse-shaped control signal (RESET) given from the outside. As shown in FIG. 16(b), in response to an input of the control signal (RESET), it is possible to make a switch between time constants in which switching time (2) required for a switch from a small time constant to a large time constant is longer than switching time (1) required for a switch from the large time constant to the small time constant.

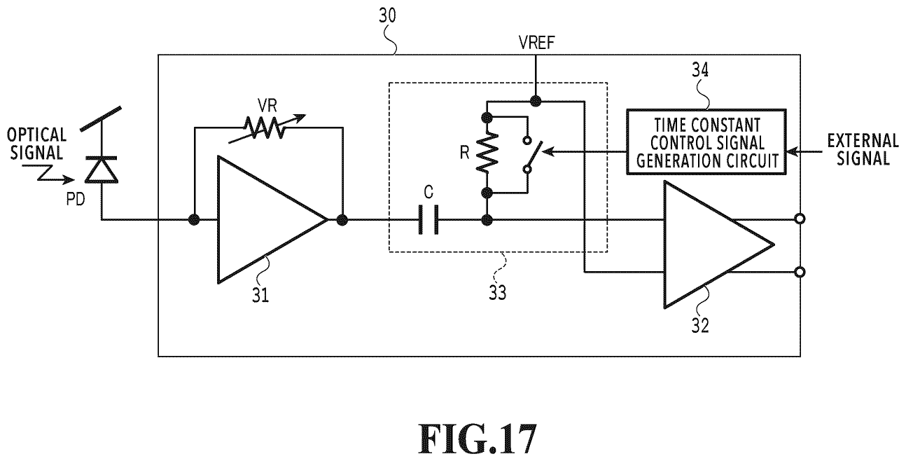

FIG. 17 is a diagram showing the configuration of the TIA according to the third embodiment. A TIA 30 connected to a PD includes a TIA core circuit 31 that amplifies a photocurrent input to an input terminal with a desired gain and outputs the photocurrent as a voltage signal, a buffer circuit 32 that amplifies differentially and outputs an output signal from the core circuit, and an AC-coupling circuit 33 that connects the TIA core circuit 31 and the buffer circuit 32. The AC-coupling circuit 33 includes the capacitor C that connects the two in series and the resistor R connected in parallel and forms a so-called high-pass filter. Further, a switch SW connected in parallel to the resistor R is provided, and a time constant control signal generation circuit 34 is used to control the time constant of the AC-coupling circuit 33.

Incidentally, as described above, in a case where the buffer circuit is configured in a multiple-stage manner, the AC-coupling circuit may also be disposed between the buffer circuit and the buffer circuit.

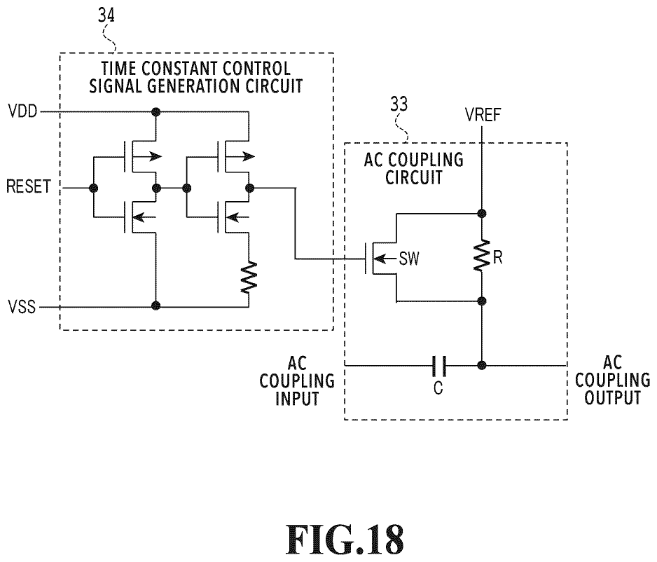

FIG. 18 is a diagram showing the circuit configuration of the AC-coupling circuit and the time constant control signal generation circuit. An FET switch SW is connected in parallel to the resistor R of the AC-coupling circuit 33, and the FET switch SW is controlled by the time constant control signal generation circuit 34. The time constant control signal generation circuit 34 includes, for example, a two-stage buffer circuit, and generates a FET switch SW control voltage with long fall time in response to an input of a rectangular control signal (RESET).

Incidentally, the configuration shown in FIG. 18 uses the FET switch connected in parallel with the resistor R of the AC-coupling circuit 33 to change the time constant, but a variable resistor may be used instead of the switch. Any configuration may be used as long as it is possible to continuously change the resistance value of the resistor that forms the high-pass filter.

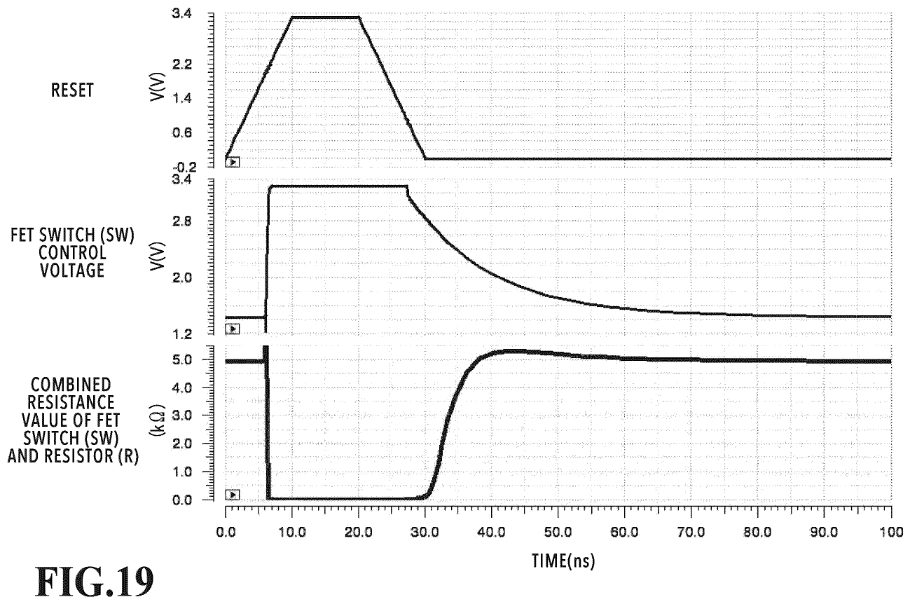

FIG. 19 is a diagram showing time constant control using the time constant control signal generation circuit. In response to a pulse-shaped control signal (RESET) given from the outside, a FET switch SW control voltage is output from the time constant control signal generation circuit 34 to the AC-coupling circuit 33. A circuit constant may be set so that the time constant defined by the combined resistance of the FET switch SW and the resistor R (4.9 kΩ) and the capacitor C falls within the range between the above-mentioned lower limit and upper limit.

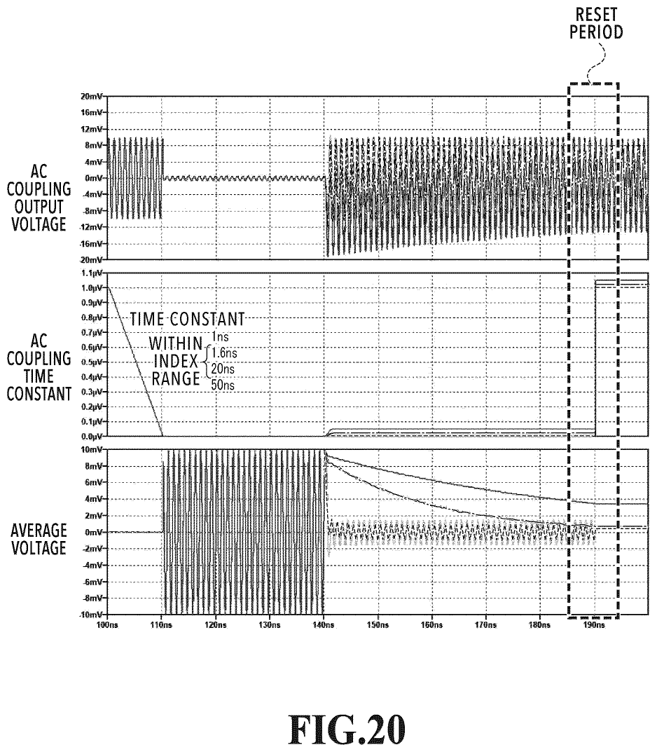

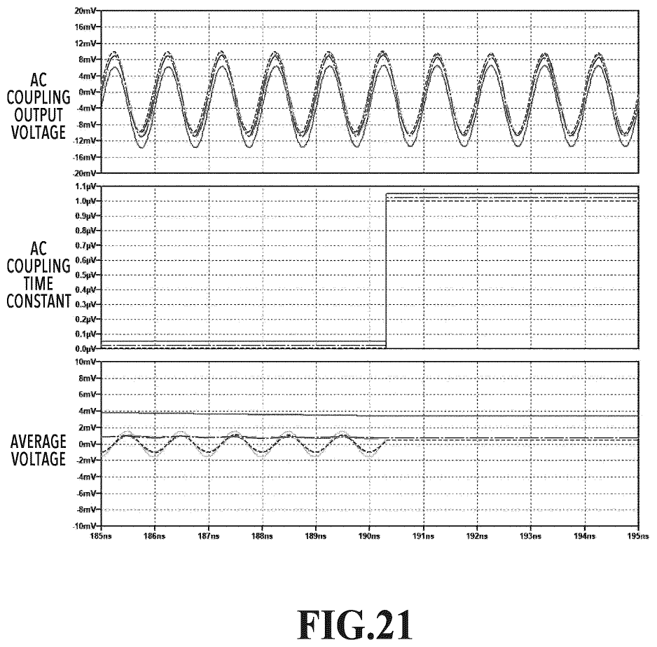

FIG. 20 is a diagram showing the output voltage of the AC-coupling circuit in a case where the time constant of the TIA according to the third embodiment is gradually changed from small to large. FIG. 21 is an enlarged view of a reset period in FIG. 20. There is shown a result of a simulation of response characteristics in cases where the time constant is 1 ns, 1.6 ns, 20 ns, and 50 ns. The output voltage, time constant, and average voltage of the output voltage of the AC-coupling circuit 33 are shown one above the other.

In a case where the frequency of an input signal is 1 GHz and the desired response time Tₛₑₜₜₗₑ is 50 nsec, a lower limit for the time constant is 1.6 nsec and an upper limit is 21.6 nsec according to the relational expression shown in the second embodiment. In a case where the time constant of the AC-coupling circuit 33 is within this range, the average voltage of the output voltage of the AC-coupling circuit 33 is ±10% or less of the amplitude of the output voltage.

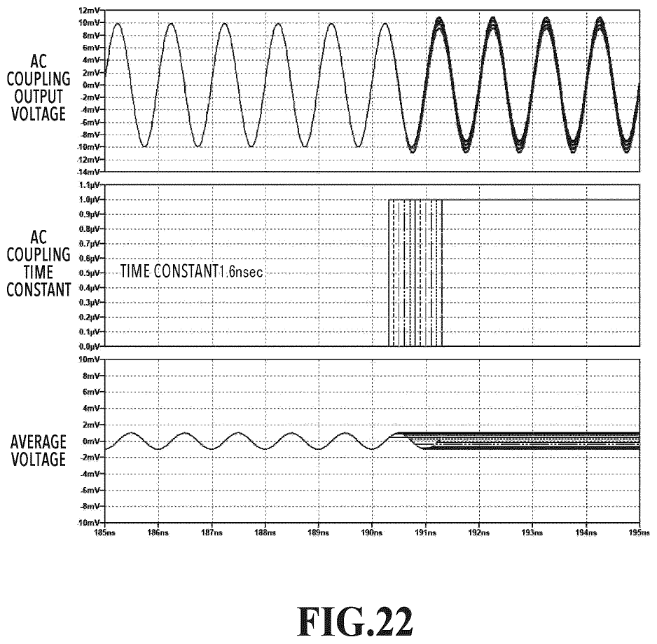

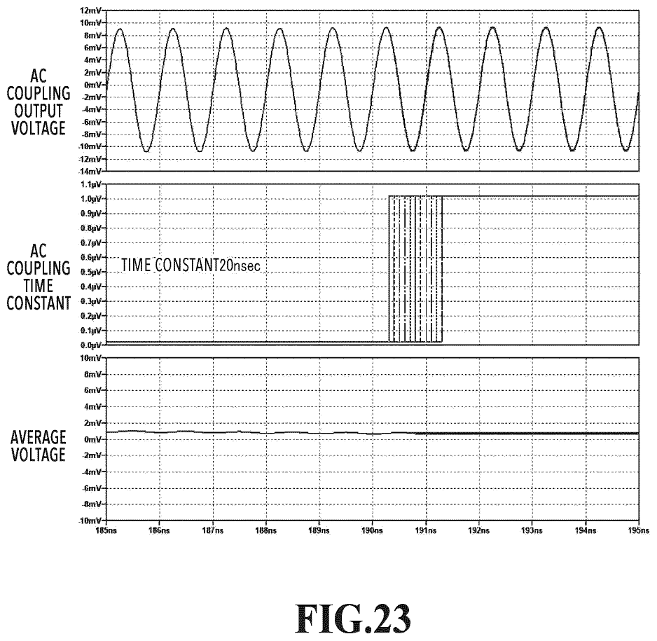

FIG. 22 is a diagram showing an AC-coupling output voltage in a case where the time constant is 1.6 ns and where the control signal (RESET) given from the outside is applied with a shifted timing to the AC-coupling input voltage. FIG. 23 is a diagram showing a case where the time constant is 20 ns. It can be seen that in either case, a normal output voltage is obtained regardless of the timing of the control signal (RESET).

### REFERENCE SIGNS LIST

10, 11-1, 20, 30 TIA
11, 21, 31 TIA CORE CIRCUIT
12, 22, 32 BUFFER CIRCUIT
23, 33 AC-COUPLING CIRCUIT
34 TIME CONSTANT CONTROL SIGNAL GENERATION CIRCUIT

1. An AC-coupling circuit comprising a switching means for switching between two different time constants in accordance with an input signal amplitude,
wherein switching time required from a small time constant to a large time constant is longer than switching time required for a switch from the large time constant to the small time constant.

2. The AC-coupling circuit according to claim 1, wherein a time constant is discretely increased during the switching from the small time constant to the large time constant.

3. The AC-coupling circuit according to claim 1, wherein a time constant is continuously increased during the switching from the small time constant to the large time constant.

4. The AC-coupling circuit according to claim 1, wherein the AC-coupling circuit is formed of a high-pass filter including a capacitor and a resistor, and
wherein the switching means switches between the two time constants by changing a resistance value of the resistor.

5. A transimpedance amplifier comprising:
a transimpedance amplifier core circuit for amplifying a current input to an input terminal with a desired gain and outputting the current as a voltage signal;
one or more buffer circuits for amplifying differentially the voltage signal from the transimpedance amplifier core circuit and outputting an output signal; and
an AC-coupling circuit disposed between the transimpedance amplifier core circuit and the buffer circuit or between the buffer circuits, the AC-coupling circuit switching between two different time constants in accordance with an amplitude of the output signal,
wherein switching time required from a small time constant to a large time constant is longer than switching time required from the large time constant to the small time constant.

6. The transimpedance amplifier according to claim 5, wherein the AC-coupling circuit is formed of a high-pass filter including a capacitor and a resistor, and
wherein the time constant is discretely increased during the switching from the small time constant to the large time constant by switching between resistance values of the resistor.

7. The transimpedance amplifier according to claim 5, wherein the AC-coupling circuit is formed of a high-pass filter including a capacitor and a resistor, and
wherein the time constant is continuously increased during the switching from the small time constant to the large time constant by changing a resistance value of the resistor.
